(19) United States
(12) Patent Application Publication
(10) Pub. No.: US 2026/0009117 A1
(43) Pub. Date: Jan. 8, 2026

(54) Manganese-Nitride Based Novel Magnetic Materials

(71) Applicant: Georgetown University, Washington, DC (US)

(72) Inventors: Zhijie Chen, Arlington, VA (US); Kai Liu, Falls Church, VA (US)

(21) Appl. No.: 18/931,500

(22) Filed: Oct. 30, 2024

Related U.S. Application Data
(60) Provisional application No. 63/594,175, filed on Oct. 30, 2023.

(51) Int. Cl. C23C 14/00; C23C 14/16; C23C 14/34; C23C 14/58; H01F 1/047; H10N 50/85

(52) U.S. Cl. CPC C23C 14/0036; C23C 14/16; C23C 14/34; C23C 14/5806; H01F 1/047; H10N 50/85

(57) ABSTRACT

A method for fabricating a magnetic material with tunable magnetic properties, comprising the reactive sputtering of a Mn₃N₂ seed layer onto a substrate, annealing at a first temperature, depositing a Mn layer onto the Mn₃N₂ seed layer, cooling to a second lower temperature, and applying a capping layer to complete the magnetic material. The resulting structure includes a Si substrate with one or more MnNₓ layer(s) with tunable nitrogen contents, and a capping layer, exhibiting adjustable magnetic properties such as exchange bias. A single Mn₄N layer can be formed with this method, so can multilayers of Mn₃N₂/Mn₂N/Mn₄N, or Mn₂N/Mn₄N, or other variations. Nitrogen partial pressure during deposition enables control of exchange bias by over an order of magnitude, while post-annealing reduces the bias by up to 70% through nitrogen migration into a neighboring tantalum layer. Voltage conditioning further tunes magnetic properties by driving nitrogen ions out of the Mn nitride layer, yielding an increased saturation magnetization and decreased exchange bias.

### CROSS-REFERENCE TO RELATED PATENT APPLICATION

The present patent application claims priority to U.S. Provisional Patent Application No. 63/594,175, filed Oct. 30, 2023, and entitled “Manganese-Nitride Based Novel Magnetic Materials”, the disclosure of which is incorporated herein by reference thereto.

### STATEMENT REGARDING FEDERALLY SPONSORED RESEARCH OR DEVELOPMENT

This invention was made with government support under grant DMR-2005108 and ECCS-2151809 awarded by the National Science Foundation. The government has certain rights in the invention.

### BACKGROUND OF THE INVENTION

The present invention relates to novel manganese (Mn)-nitride magnetic materials.

Spintronics is an emerging field where the electron spin, in addition to the electron charge, is used to carry and manipulate digital information. It has been shown to potentially transform computer memory market with the emergency and adaptation of magnetic random-access memory (MRAM). Moreover, it may revolutionize nanoelectronics with the creation of post-Complementary Metal-Oxide-Semiconductor (COMS) and neuromorphic technologies.

Currently, most magnetic materials employed in spintronics are critical materials based on cobalt or rare-earth elements, which pose environmental challenges and are prone to geopolitical factors. A promising alternative material for more sustainable spintronics is the manganese-nitride family of materials, composed of economically viable and earth-abundant elements.

Mn nitrides have a rich phase diagram comprising of both antiferromagnets (AF) and ferrimagnet (FiM), namely θ-MnN (AF), η-Mn₃N₂ (AF), ξ-Mn₂N (AF), and ε-Mn₄N (FiM). Among these, Mn₄N stands out as the only FiM Mn nitride phase and has gained considerable attention in recent years as an emergent rare-earth-free and heavy-metal-free sustainable spintronics material. FiM harnesses the combined benefits of both ferromagnetic (FM) and antiferromagnetic (AF) materials, an area currently undergoing intense research. The Mn₄N has a high Curie temperature of 745 K, ensuring excellent thermal stability. Its low saturation magnetization translates into faster switching speeds and reduced stray magnetic fields. Additionally, the Mn₄N thin film possesses perpendicular magnetic anisotropy (PMA), a highly desirable characteristic under specific growth conditions, which renders it apt for numerous spintronic device implementations. It exhibits a substantial domain wall velocity and potential for hosting non-trivial spin textures, making it suitable for domain-wall and skyrmion-based magnetic memory applications. However, it's important to note that the growth of Mn₄N films presently requires specific substrates and precise nitrogen environments, limiting its wider practical application.

As further background, the rise of generative artificial intelligence (AI) has led to significant advancements and widespread application of large language models like ChatGPT. However, training and maintaining these models require substantial computational resources, leading to a considerable increase in power consumption. Additionally, the storage demands for vast amounts of data have resulted in a surge of newly constructed data centers, further exacerbating energy requirements. Addressing the escalating energy consumption in information technology has become a pressing concern. One promising solution lies in the voltage control of magnetism (VCM), which promises significantly reduced energy consumption by eliminating Joule heating and maintaining compatibility with the semiconductor industry. To this end, there has been a resurgence of interest in multiferroic and magnetoelectric material. Despite its great potential, it often faces challenges related to non-volatility, limited tunability, and scalability.

Magneto-ionics is an emerging field that explores the control of magnetic properties through the movement of ions. This approach has gained significant attention due to its potential to enable energy-efficient magnetic switching and the modulation of materials properties, which are critical for next-generation memory, spintronics, and neuromorphic computing applications. Several methods have been developed to induce the ionic motion, including electrolyte gating, solid-state gating, chemisorption, and redox reactions. These approaches allow for the regulation of magnetic properties such as saturation magnetization, magnetic anisotropy, exchange bias, Dzyaloshinskii-Moriya interaction, and spin textures. Moreover, various ionic species such as oxygen, hydrogen, nitrogen, hydroxide, and lithium have been investigated for their effectiveness in magneto-ionic applications. Recent studies have highlighted the advantages of nitrogen-based magneto-ionics, which demonstrate faster ionic motion and enhanced reversibility, making them particularly promising for future applications.

Accordingly, there is a need for a scalable, all-Mn nitride solid state system that provides an environmentally friendly platform with highly tunable magnetic properties, as well as for efficient methods to produce such Mn nitride materials.

### SUMMARY OF THE INVENTION

A novel, ionically driven synthesis method for growing Mn₄N films is disclosed. Magnetic properties such as exchange bias in this Mn₄N system which can be ionically controlled is also demonstrated.

The novel ionically driven synthesis method may be used to grow high-quality ordered Mn₄N thin films on Si substrates by directly sputtering pure Mn onto an Mn₃N₂ seed layer at elevated temperatures, resulted from the chemical reaction between Mn and the nitrogen in the Mn₃N₂ seed layer. This Mn₄N film also has similar magnetic properties such as perpendicular magnetic anisotropy and small saturation magnetization when compared to others.

A method of fabricating a magnetic material is disclosed. One general aspect of the method includes reactively sputtering a Mn₃N₂ seed layer onto a substrate at a first temperature, annealing the Mn₃N₂ seed layer at the first temperature, depositing a Mn layer onto the Mn₃N₂ seed layer at the first temperature, wherein the substrate, Mn₃N₂ seed layer, and deposited Mn layer form a sample, cooling the sample to a second temperature lower than the first temperature, and depositing a capping layer onto the sample to form the magnetic material.

A magnetic material fabricated by the method of claim 1, is disclosed. The magnetic material comprises a substrate, a Mn₃N₂ seed layer reactively sputtering annealing onto the substrate at a first temperature, a Mn layer deposited onto the Mn₃N₂ seed layer at the first temperature, wherein the substrate, Mn₃N₂ seed layer, and deposited Mn layer form a sample, and a capping layer deposited onto the sample to form the magnetic material, wherein the material exhibits a tunable exchange bias and saturation magnetization and perpendicular magnetic anisotropy for spintronic device applications.

The magnetic properties such as the exchange bias effect in the Mn₄N systems can be varied by up to an order of magnitude by changing the nitride layers' nitrogen content. This is accomplished by varying nitrogen partial pressure during deposition or changing post-annealing temperature. Increasing nitrogen partial pressure during deposition increases the nitrogen content and exchange bias, while post-annealing removes the nitrogen from the nitride layer and decreases the exchange bias. Additionally, magnetic properties such as exchange bias and saturation magnetization can be tuned using room temperature solid state voltage application. An increase in saturation magnetization by 23% and decrease in exchange bias by 15% is achieved by driving nitrogen out of the nitrides with positive voltage application. These changes can be reversed followed by a negative voltage application.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and the invention may admit to other equally effective embodiments.

FIGS. 1a-1d illustrate example structural and magnetic characterizations for Mn₃N₂ and Mn₄N.

FIGS. 2a-2e illustrate example structural characterizations for the thickness series.

FIGS. 3a-3b illustrate example graphs showing X-ray diffraction results for the thickness series.

FIG. 4 illustrates example diagram showing nitride phase evolution in the thickness series.

FIGS. 5a-5h illustrate example graphs showing transmission electron microscopy results for samples in the thickness series.

FIGS. 6a-6c illustrate example graphs showing room-temperature magnetometry results for samples in the thickness series.

FIGS. 7a-7j illustrate example graphs showing first-order reversal curves (FORC) and FORC distributions for samples in the thickness series.

FIGS. 8a-8c illustrate example graphs showing exchange bias effect for the thickness series.

FIGS. 9a-9g illustrate example structural characterizations for the nitrogen series.

FIGS. 10a-10b illustrate example graphs showing X-ray diffraction results for the nitrogen series.

FIGS. 11a-11h illustrate example graphs showing FORCs and FORC distributions for samples in the nitrogen series.

FIGS. 12a-12d illustrate example graphs showing exchange bias and training effect for the nitrogen series.

FIGS. 13a-13d illustrate example graphs showing temperature and cooling field dependence of the exchange bias effect for the nitrogen series.

FIGS. 14a-14d illustrate graphs showing structural and exchange bias variation for the annealing series.

FIGS. 15a-15b illustrate example graphs showing X-ray diffraction results for the annealing series.

FIGS. 16a-16h illustrate example graphs showing FORCs and FORC distributions for samples in the annealing series.

FIGS. 17a-17i illustrate visualization of voltage control of magnetism in the Mn nitrides.

FIGS. 18a-18c illustrate example visualizations of scattering length density (SLD) depth profile from polarized neutron reflectivity (PNR).

FIG. 19 illustrates a method for fabricating magnetic materials according to an exemplary embodiment of the disclosure.

Other features of the present embodiments will be apparent from the Detailed Description that follows.

### DETAILED DESCRIPTION

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention. Electrical, mechanical, logical, and structural changes may be made to the embodiments without departing from the spirit and scope of the present teachings. The following detailed description is therefore not to be taken in a limiting sense, and the scope of the present disclosure is defined by the appended claims and their equivalents.

The following disclosure discusses the present invention with reference to the examples shown in the accompanying drawings, though does not limit the invention to those examples.

The use of any and all examples, or exemplary language (e.g., “such as”) provided herein is intended merely to better illuminate the invention and does not pose a limitation on the scope of the invention unless otherwise claimed. No language in the specification should be construed as indicating any non-claimed element as essential or otherwise critical to the practice of the invention, unless made clear in context.

As used herein, the singular forms “a,” “an,” and “the” include plural referents unless the context clearly dictates otherwise. Unless indicated otherwise by context, the term “or” is to be understood as an inclusive “or.” Terms such as “first”, “second”, “third”, etc. when used to describe multiple devices or elements, are so used only to convey the relative actions, positioning and/or functions of the separate devices, and do not necessitate either a specific order for such devices or elements, or any specific quantity or ranking of such devices or elements.

The word “substantially”, as used herein with respect to any property or circumstance, refers to a degree of deviation that is sufficiently small so as to not appreciably detract from the identified property or circumstance. The exact degree of deviation allowable in a given circumstance will depend on the specific context, as would be understood by one having ordinary skill in the art.

Use of the terms “about” or “approximately” are intended to describe values above and/or below a stated value or range, as would be understood by one having ordinary skill in the art in the respective context. In some instances, this may encompass values in a range of approx. +/−10%; in other instances there may be encompassed values in a range of approx. +/−5%; in yet other instances values in a range of approx. +/−2% may be encompassed; and in yet further instances, this may encompass values in a range of approx. +/−1%.

It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof, unless indicated herein or otherwise clearly contradicted by context.

Recitations of a value range herein, unless indicated otherwise, serves as a shorthand for referring individually to each separate value falling within the stated range, including the endpoints of the range, each separate value within the range, and all intermediate ranges subsumed by the overall range, with each incorporated into the specification as if individually recited herein.

Unless indicated otherwise, or clearly contradicted by context, methods described herein can be performed with the individual steps executed in any suitable order, including: the precise order disclosed, without any intermediate steps or with one or more further steps interposed between the disclosed steps; with the disclosed steps performed in an order other than the exact order disclosed; with one or more steps performed simultaneously; and with one or more disclosed steps omitted.

The present disclosure relates to the fabrication of magnetic materials, strength, corrosion resistance, in addition to also having desirable magnetic properties. This disclosure also describes how to fabricate magnetic materials.

In this disclosure, the ionically-driven synthesis and magneto-ionic control of this all-nitride Mn₄N/MnNₓ system is disclosed. Specifically, high-quality Mn₄N thin films can be grown on Si substrates by directly sputtering pure Mn onto an Mn₃N₂ seed layer at elevated temperatures, resulted from the chemical reaction between Mn and the nitrogen in the Mn₃N₂ seed layer. The exchange bias effect in this system can be increased by over an order of magnitude by introducing more nitrogen into the system during deposition and subsequently reduced by over 70% by taking nitrogen out of the system through post-annealing. Additionally, voltage-induced nitrogen ionic motion can lead to reversible changes in saturation magnetization and exchange bias effect by 23% and 15% at 5 K, respectively. These findings highlight the potential of this all-Mn nitride solid state system as a scalable and environmentally friendly platform with remarkable tunability of magnetic properties.

### Fabrication Method

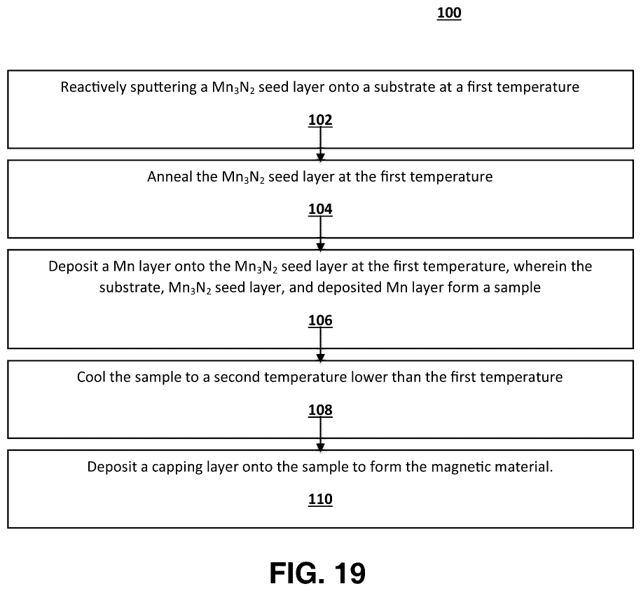

FIG. 19 shows a method 100 for fabricating magnetic materials according to an exemplary embodiment of the disclosure. The method 100 includes reactively sputtering a Mn₃N₂ seed layer onto a substrate at a first temperature 102, annealing the Mn₃N₂ seed layer at the first temperature 104, depositing a Mn layer onto the Mn₃N₂ seed layer at the first temperature, wherein the substrate, Mn₃N₂ seed layer, and deposited Mn layer form a sample 106, cooling the sample to a second temperature lower than the first temperature 108, and depositing a capping layer onto the sample to form the magnetic material 110.

First embodiment (thickness series): Seed layers of 20 nm Mn₃N₂ were first reactive sputtered onto Si substrate with 285 nm thermally oxidized SiO₂ layer from a Mn target using direct current (dc) in an ultrahigh vacuum chamber with a base pressure better than 5×10⁻⁸ Torr. The substrate temperature was kept at 450° C., and the Ar:N₂ ratio was held at 1:1 with a 5 mTorr sputtering gas pressure. These Mn₃N₂ films were then left in vacuum for 30 min at the same substrate temperature to promote nitrogen reordering. Subsequently, 0-50 nm of Mn was deposited onto the Mn₃N₂ layer at the same 450° C. substrate temperature in an Ar-only environment. After deposition, substrate heating was immediately turned off, and the samples were cooled to room temperature before depositing a 5 nm Ti capping layer to prevent oxidation. These samples are referred to as the thickness series.

Mn₃N₂ seed layer of varying thickness (x nm) were fabricated using the same method as the first embodiment. Subsequently, nominally 2*x nm Mn was deposited onto the Mn₃N₂ layer at the same 450° C. substrate temperature with nitrogen partial pressures (P_{N}) varying from 0% to 6%, where

$${P}_{N} = \frac{{N}_{2} flow rate}{Ar + {N}_{2} flow rate} \times 100 \% .$$

After deposition, substrate heating was turned off immediately and the samples were cooled to room temperature before depositing a Ti or Ta capping layer. All samples were fabricated using this method and only thickness x, P_{N}, and capping layer varies between the sample series.

Second embodiment (nitrogen series): x=20 for all the samples, and the capping layer is 5 nm Ti. P_{N} varies from 0% to 6%. Similar samples were used for neutron measurements. These samples are referred to as the nitrogen series.

Third embodiment (annealing series): x=20 and P_{N} is fixed at 6% for all samples. Samples were capped with 50 nm Ta instead of 5 nm Ti. Each sample from the annealing series was annealed at different temperatures in vacuum for 1 minute. Similar samples were also used for neutron measurements. These sample are referred to as the annealing series.

Forth embodiment (gating series): x=5 and Ta capping layer is 10 nm. P_{N} were all fixed at 6%. These samples are referred to as the gating series.

### First Embodiment (Thickness Series)

For the first embodiment, the thickness series samples are used to demonstrate how the ionically driven synthesis method can be used to grow high quality Mn₄N thin films with desirable magnetic properties.

Mn₄N thin films are typically grown onto SrTiO₃ or MgO substrates at elevated temperatures through molecular beam epitaxy, pulsed laser deposition, or reactive sputtering in a nitrogen environment. The film quality is susceptible to the nitrogen flow rate or partial pressure, and the optimum growth conditions vary from study to study. It is challenging to grow high-quality thin films of Mn₄N directly on Si substrates, which are CMOS compatible. In this disclosure, it is demonstrated that high-quality (001)-ordered Mn₄N thin films can be grown on Si substrates by directly sputtering pure Mn onto an Mn₃N₂ seed layer at elevated temperatures, resulted from the chemical reaction between Mn and the nitrogen in the Mn₃N₂ seed layer. In a nominally Mn₃N₂ (20 nm)/Mn (t_{Mn}) series of samples, by changing the deposited Mn thickness t_{Mn} from 0 to 50 nm, nitrogen ion migration gradually transforms the layers into Mn₃N₂/Mn₂N/Mn₄N, Mn₂N/Mn₄N and eventually Mn₄N, confirmed by X-ray diffraction (XRD), transmission electron microscopy (TEM), and electron energy loss spectroscopy (EELS). The Mn₄N films are found to exhibit PMA. First-order reversal curve (FORC) measurements reveal that the Mn₄N forms with a nucleation-and-growth process. The nitrogen ion migration is also manifested in a significant exchange bias, up to 0.3 T at 5 K, due to the interaction between ferrimagnetic Mn₄N and antiferromagnetic Mn₃N₂ and Mn₂N.

Structural characterizations were performed using XRD on a Panalytical X'Pert³ MRD with symmetric 2θ-ω and grazing incidence geometries. Sample microstructures and composition analysis were done using an FEI Titan Themes Cubed G2 300 (Cs Probe) TEM at KAUST. The cross-sectional TEM lamellas were fabricated using the Helios G4 UX FIB system (Thermo Fisher Scientific) with a Ga⁺ beam source. Low-energy (2-5 kV) final polishing was employed to minimize the irradiation damage. The composition ratio of Mn and N was determined by EELS line-scan analysis using FEI Titan Themes Cubed G2 300 (Cs Probe) TEM at 300 kV. Magnetic measurements were carried out using a Quantum Design superconducting quantum interference device (SQUID) magnetometer. Exchange bias was measured at 5 K by first field-cooling the sample from 300 K in a 2 T magnetic field, all in the out-of-plane (OP) geometry. FORC measurements were done in a vibrating sample magnetometer at room temperature.

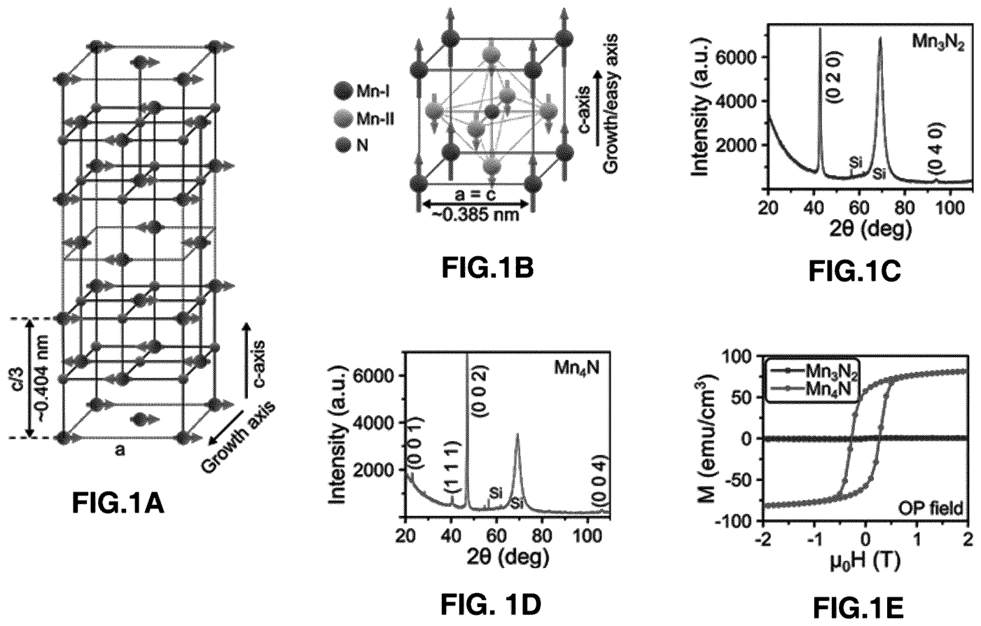

The n-phase Mn₃N₂ is chosen as the seed layer for Mn₄N growth because it provides the crystalline texture and nitrogen needed for the Mn₄N growth. As shown in FIGS. 1a and 1b, Mn₃N₂ is antiferromagnetic (T_{N}˜925 K), and its c-axis is about three times that of Mn₄N. XRD reveals the successful growth of the Mn₃N₂ phase, shown in FIG. 1c, with a preferred orientation along the (010) direction and the c-axis in the film plane. Upon depositing 40 nm of Mn, XRD shows that the film is primarily the Mn₄N phase with a (001)-orientation, with no appreciable Mn₃N₂ phase left, as shown in FIG. 1d. Along with the structure changes, there is also a drastic change in the film magnetic properties. As shown in FIG. 1e, the initial Mn₃N₂ layer does not exhibit any magnetic signal, consistent with its antiferromagnetic nature; interestingly, the sample deposited with Mn exhibits a square loop with a large coercivity (0.27 T) and a small M_{S} (85 emu/cm³) that are typical of Mn₄N films.

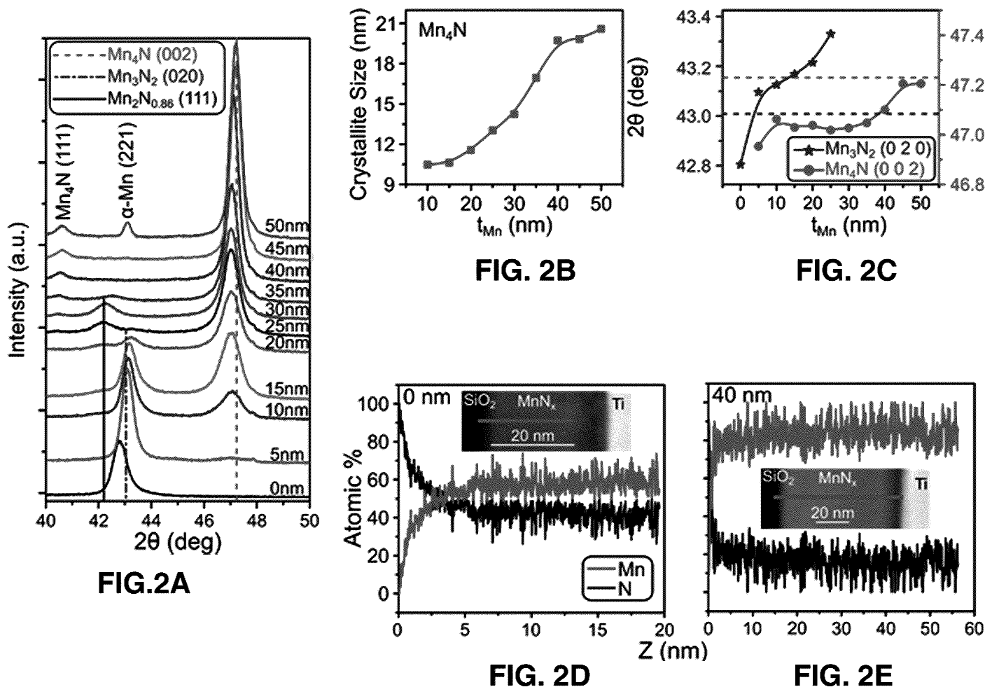

To understand how the film transforms from Mn₃N₂ to Mn₄N by only depositing Mn, a series of samples starting with 20 nm Mn₃N₂ seed layer is investigated, but the deposited Mn nominal thickness varied from 0 to 50 nm with a 5 nm step size. From now on, each sample is referred by its deposited Mn thickness (t_{Mn}) unless otherwise stated. FIG. 2a reveals how the Mn nitride phase evolves across the samples. Starting from t_{Mn}=0 nm, which is the Mn₃N₂ layer, the only peak is the Mn₃N₂ (020). As t_{Mn} increases, a prominent peak emerges around 47.2°, corresponding to the Mn₄N (002), indicating Mn₄N formation as Mn is deposited. On the other hand, the Mn₃N₂ (020) peak diminishes and shifts to higher angles before eventually vanishing in the t_{Mn}=30 nm sample. This trend indicates that the Mn₃N₂ phase is fading and is not as stable as Mn₄N at high temperatures, consistent with prior studies. Interestingly, as the Mn₃N₂ peak's integrated intensity gets smaller, another peak emerges near 2θ=42.2° in the t_{Mn}=20 nm sample and grows larger before disappearing in the t_{Mn}=40 nm sample. This peak is the (111) Bragg peak from the ξ-phase Mn₂N_{0.86}, which has a thermal stability and nitrogen content between η-Mn₃N₂ and ε-Mn₄N. In the t_{Mn}=40 and 45 nm samples, both Mn₃N₂ and Mn₂N peaks have vanished, while the Mn₄N (002) peak gets even larger and closer to its expected 2θ value. Eventually, when t_{Mn} reaches 50 nm, the α-Mn (221) peak shows up near 2θ=43°, indicating that some deposited Mn remain unreacted as the entire nitride film is now Mn₄N.

The Mn₄N crystallite size has been estimated from the full-width-at-half-maximum (FWHM) of the (002) peak, after instrument broadening correction, using the Scherrer equation. The Mn₄N crystallite size nearly doubles as more Mn is deposited, reaching a plateau after t_{Mn}=40 nm, as shown in FIG. 2b. This is consistent with the trend in FIG. 2a, where the Mn₄N peak becomes sharper and more prominent, and Mn₄N is the only phase after t_{Mn} reaches 40 nm. This crystallite size estimation is rather simplified, as it ignores peak width contribution from other factors such as inhomogeneities in d-spacing. As the film stoichiometry changes due to the nitrogen migration, any spread in N-content and the lattice parameters would lead to a broadening of the peak width. Interestingly, the overall narrowing trend of the Mn₄N peak width with increasing t_{Mn} suggests that the stoichiometry variation is suppressed at high t_{Mn}, which is consistent with the fact that when t_{Mn} reaches 40 nm, only a single phase Mn₄N is observed. Moreover, the peak locations shift to higher angles as t_{Mn} increases, as shown in FIG. 2c. Nitride phases' lattice constants are known to be very sensitive to nitrogen content, as interstitial nitrogen usually causes the lattices to expand. As Mn₃N₂ loses nitrogen to the deposited Mn, its lattice contracts, causing the Mn₃N₂ peak to shift to a higher angle until this phase is gone. The Mn₄N peak location, on the other hand, stays relatively constant before changing rapidly beyond t_{Mn}=40 nm, likely caused by the nitrogen redistribution within the Mn₄N phase once the nitrogen from Mn₃N₂ and Mn₂N has been depleted. Thus, it may be postulated that as Mn is deposited onto the Mn₃N₂ layer at elevated temperatures, it reacts with the nitrogen coming from Mn₃N₂ and forms Mn₄N. While Mn₃N₂ loses nitrogen, it first turns into Mn₂N and eventually becomes Mn₄N. These reactions are summarized in the following reaction equations,

$$2 {Mn}_{3} {N}_{2} \to 3 {Mn}_{2} N + N ; 4 Mn + N \to {Mn}_{4} N ; 2 {Mn}_{2} N \to {Mn}_{4} N + N$$

and they can be combined into one chemical reaction since they are multistep reactions.

$$5 Mn + {Mn}_{3} {N}_{2} \to 2 {Mn}_{4} N .$$

The enthalpy of formation for this reaction is calculated to be −110 kJ/mol using the standard enthalpy of formation for Mn₄N and Mn₃N₂, indicating that this reaction is thermodynamically favorable.

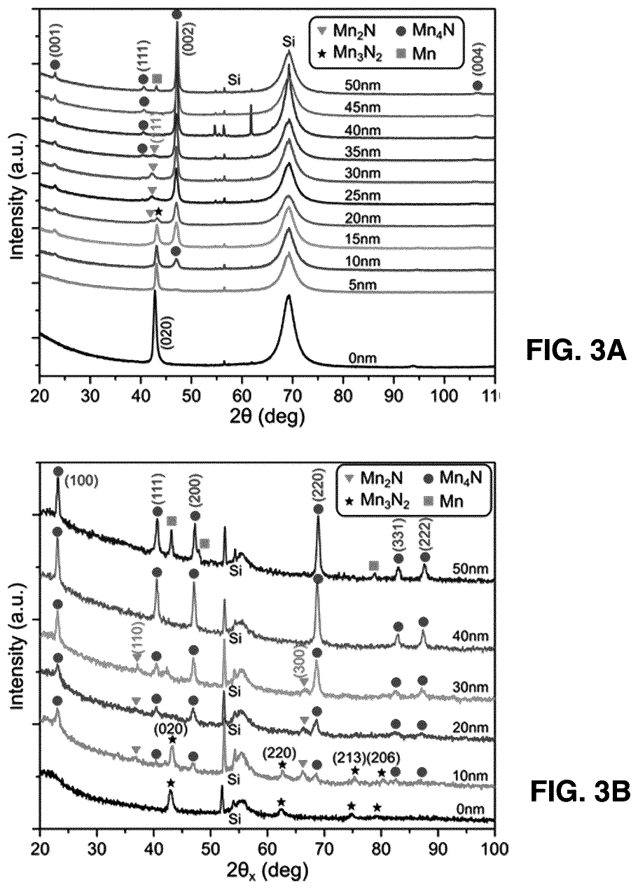

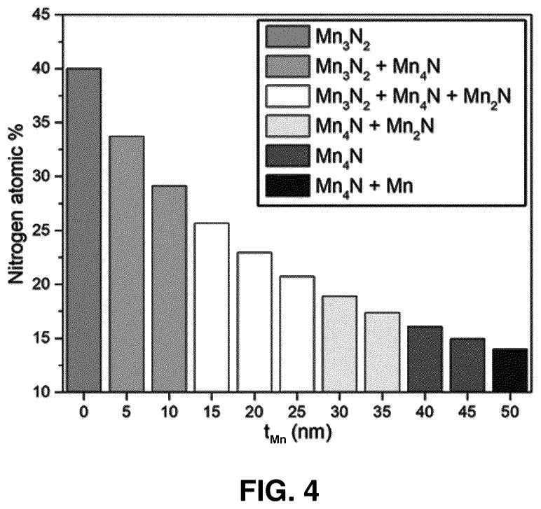

For completeness, full range 2θ-ω and grazing incidence scans are shown in FIGS. 3a and 3b. Starting with t_{Mn}=0 nm, which is the 20 nm Mn₃N₂ seed layer (black lines), all the peaks (black stars) are from the Mn₃N₂ phase. As t_{Mn} increases to 10 nm (red lines), Mn₄N peaks (blue circles) emerge because of the reaction between Mn and nitrogen from Mn₃N₂. Mn₂N peaks (red triangles) also show up as Mn₃N₂ loses nitrogen. At t_{Mn}=20 nm, Mn₃N₂ peaks are all gone after losing too much nitrogen while the Mn₄N peaks grow. Mn₂N peaks, on the other hand, persist until t_{Mn}=40 nm as the Mn₂N phase loses nitrogen and turns into Mn₄N. In the meantime, Mn₄N peaks grow taller and sharper. At t_{Mn}=50 nm, there is no nitrogen available for Mn to react with and form Mn₄N. Thus, α-Mn peaks show up. These results are consistent with the interpretation of the XRD scans shown in FIG. 2a. The phase diagram in FIG. 4 may be summarized accordingly, which is based on expected nitrogen atomic percent and Mn nitride phases identified in each sample from XRD. The expected nitrogen atomic percent is calculated using the nominal Mn₃N₂ seed layer thickness and the Mn thickness deposited on top (t_{Mn}).

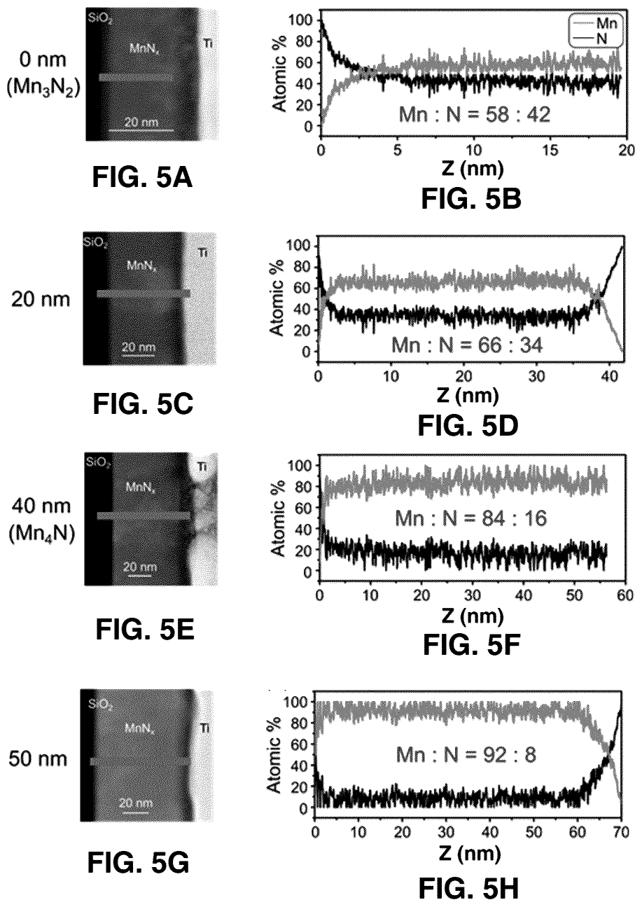

EELS line scans are collected from samples with t_{Mn}=0, 20, 40, 50 nm (FIG. 5). The TEM images (left column) indicate the Mn nitride layers are mostly homogenous without distinctive interfaces for all four samples. EELS scans measured across the green lines in the TEM images show that the composition ratio of Mn:N is continuously varying due to the ionic motion of nitrogen within the nitride layers. At t_{Mn}=0 nm, atomic ratio of Mn:N is 58:42, consistent with the nominal atomic ratio of Mn₃N₂. As t_{Mn} increases, nitrogen redistribute within the Mn nitride layers and the Mn:N ratio changes to 66:34 for t_{Mn}=20 nm and 84:16 for t_{Mn}=40 nm. This is also consistent with XRD results (FIG. 3) that indicate Mn₄N is the only nitride phase at t_{Mn}=40 nm. When t_{Mn} increases to 50 nm, atomic percent ratio further increases to 92:8, likely because of the existence of pure Mn as shown in XRD (FIG. 3). Note that there is some non-uniformity near the interfacial region between the substrate/capping layer and nitride layers, likely caused by interfacial mixing effect, as nitrogen tends to go into the substrate and capping layer more than Mn. Interestingly, most of the nitride layers appear homogenous with constant Mn:N ratio from both the cross-sectional TEM and EELS, indicating that nitrogen in the Mn₃N₂ seed layer has redistributed to maintain a constant nitrogen concentration within the Mn nitrides after the Mn is deposited. These results further corroborate the postulation that nitrogen moves from the Mn₃N₂ seed layer into the Mn layer to form more stable Mn₄N.

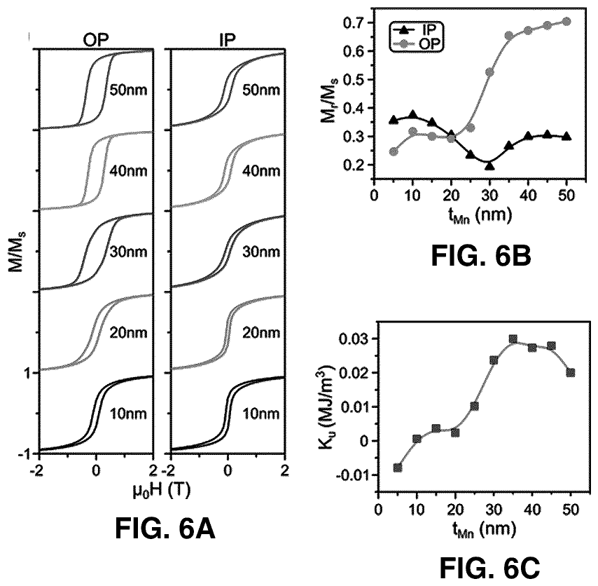

The magnetic properties of this series of samples may be investigated. FIG. 6a shows the room temperature hysteresis loops with in-plane (IP) and out-of-plane (OP) magnetic fields. The OP loops get more square and broader as t_{Mn} increases from 10 to 50 nm while the IP loops stay relatively constant. These trends are further revealed by plotting the squareness, or ratio of remanence magnetization (Mᵣ) over M_{S}, for each sample, FIG. 6b. The OP and IP remanence are small and stay relatively constant for t_{Mn}<20 nm, indicating the lack of a clear magnetic easy axis. For 20 nm<t_{Mn}<35 nm, a sharp jump in OP remanence is observed, along with a drop in IP remanence, indicating a clear easy axis has been established in the OP direction. At t_{Mn}>35 nm, the easy axis remains OP, while IP remanence increases slightly but remains low.

The uniaxial magnetic anisotropy constant (Kᵤ) may be calculated using

$${K}_{u} = {K}_{u}^{eff} + \frac{{μ}_{0}}{2} {M}_{S}^{2} , where {K}_{u}^{eff}$$

is the effective anisotropy estimated from the area difference between the IP and OP hysteresis loops and

$$\frac{{μ}_{0}}{2} {M}_{S}^{2}$$

is the thin film demagnetization energy. As shown in FIG. 6c, Kᵤ starts out to be negative for t_{Mn}=5 nm and shows a clear switching from negative to positive, especially when t_{Mn}>20 nm, further confirming the magnetic easy axis switching to OP as more Mn₄N is formed. Note that Kᵤ exhibits the largest value (0.03 MJ/m³), or the film has the largest PMA when 35 nm<t_{Mn}<45 nm. This is also consistent with the XRD result, which shows that Mn₄N is the only phase for this t_{Mn} range. This Kᵤ value is smaller than other reported values which range from 0.05 to 0.2 MJ/m³. The uniaxial anisotropy has been attributed to the tetragonal distortion caused by in-plane tensile strains. The reason for the smaller Kᵤ values since the films are deposited onto an amorphous SiO₂ layer that doesn't provide in-plane strain.

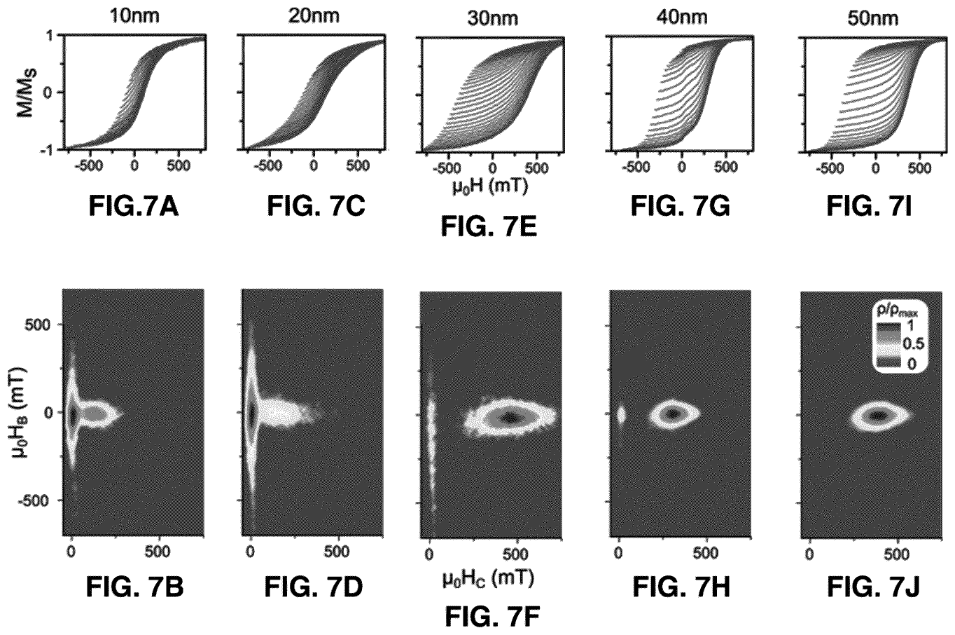

To investigate how the Mn₄N phase evolves with t_{Mn} and the corresponding magnetization reversal, FORC studies in the OP geometry may be carried out at room temperature, as shown in FIG. 7. For the t_{Mn}=10 and 20 nm samples, individual FORCs fill the major loops in a slanted fashion, FIGS. 7a and 7c, respectively. The corresponding FORC distributions exhibit a prominent vertical ridge centered around H_{C}=0, which corresponds to reversible switching, and a smaller horizontal feature centered at μ₀H_{C}=120 mT and 150 mT, respectively (FIGS. 7b and 7d). This indicates that the Mn₄N film is mainly reversible and magnetically soft. Likely for this t_{Mn} range, the Mn₄N phase is just emerging in small clusters scattered in an antiferromagnetic matrix of Mn₃N₂ and Mn₂N. As more Mn₄N is formed, families of FORCs for t_{Mn}=30, 40, and 50 nm differ considerably, as individual FORCs return to positive saturation in a more horizontal fashion, consistent with the establishment of a magnetic easy axis (FIGS. 7e, g, and i). Their FORC distributions are also strikingly different. The previous large vertical reversible ridge at μ₀H_{C}=0 becomes smaller and eventually vanishes in the t_{Mn}=50 nm sample. The horizontal feature along the H_{C} axis now becomes prominent and shifts to higher μ₀H_{C} of 460, 310, and 390 mT, respectively (FIG. 7f, 7h, and 7j). The change in relative intensity of the horizontal and vertical FORC features likely indicate that Mn₄N forms via a nucleation-and-growth mechanism, similar to that reported previously in the ordering of L1₀FeCuPt.

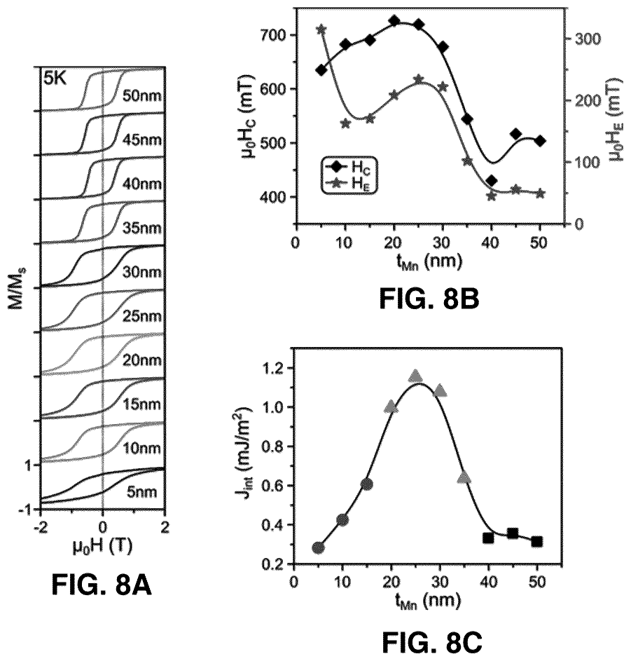

In this nominally Mn₃N₂ (20 nm)/Mn (t_{Mn}) series of samples, the evolution of the AF phase and the emergence of the FiM phase are also manifested in the exchange bias effect, which was studied at 5 K after cooling the samples from room temperature in a positive 2 T OP magnetic field. A significant horizontal shift to the negative field direction, up to 300 mT, and a coercivity enhancement can be seen, FIG. 8a, typical of exchange bias systems. The t_{Mn} dependence of coercivity (H_{C}) and exchange field (H_{E}) both exhibit non-monotonic trends, with an intriguing peak around 20 nm<t_{Mn}<30 nm, as shown in FIG. 8b. These trends are likely a combined effect from the AF phase evolution as well as the FiM thickness and M_{S} variations. To further explore the exchange anisotropy independent of the FiM, the interfacial exchange energy (Jᵢₙₜ) per unit area may be evaluated using the following equation:

$${J}_{int} = {M}_{FiM} {t}_{FiM} {H}_{E} = {m}_{FiM} {H}_{E} / A ,$$

where M_{FiM}, m_{FiM}, and t_{FiM} are the FiM saturation magnetization, saturation magnetic moment, and layer thickness, respectively, H_{E} is the exchange field, and A is the sample area. As shown in FIG. 8c, the dependence of Jᵢₙₜ on t_{Mn} exhibits a bell-shaped plot that peaks around 20 to 30 nm. Jᵢₙₜ is small and increases continuously for t_{Mn} of 5-15 nm, where the dominating AF phase is Mn₃N₂, as observed by XRD. Due to the high T_{N} of Mn₃N₂, only a small fraction of the AF spins is aligned to pin Mn₄N by field cooling from room temperature, resulting in a small Jᵢₙₜ. However, for 20 nm<t_{Mn}<35 nm samples, another AF phase, Mn₂N, starts to dominate. By field cooling from 300 K, the Mn₂N is effectively coupled with Mn₄N, resulting in a significant exchange bias at 5 K. Exchange energy then quickly decreases as Mn₂N is turned into Mn₄N. By t_{Mn}=40 nm, no AF phases can be identified from XRD and Jᵢₙₜ mostly vanishes.

In summary, high-quality Mn₄N films growth may be achieved by depositing pure Mn onto an Mn₃N₂ seed layer. By varying the Mn thickness t_{Mn}, the nitrogen concentration in the starting Mn₃N₂/Mn bilayers can be continuously tuned to be Mn₃N₂/Mn₂N/Mn₄N, Mn₂N/Mn₄N, and eventually to Mn₄N alone, as observed by XRD and TEM/EELS. With increasing t_{Mn}, more Mn₄N is formed, with an increasing PMA reaching 0.03 MJ/m³. FORC measurements further reveal that Mn₄N forms via a nucleation-and-growth mechanism. A large exchange bias up to 0.3 T is found at 5 K in this all-nitride system. The variation of the exchange anisotropy is further attributed to the phase change of the antiferromagnets caused by nitrogen redistribution. These results demonstrate an effective all-nitride magneto-ionic platform for studying the properties of the emergent ferrimagnetic Mn₄N and its potential applications in spintronics.

### Second Embodiment (Nitrogen Series)

Thus, it is shown that Mn₄N can be formed by depositing Mn on top of a Mn₃N₂ seed layer at elevated temperatures, resulting from the chemical reaction between Mn and Mn₃N₂. By varying Mn thickness, the layers can be transformed from Mn/Mn₃N₂ to Mn₄N/Mn₂N/Mn₃N₂, Mn₄N/Mn₂N, and eventually Mn₄N alone. In the second embodiment, the fabrication and control of exchange bias with adding nitrogen in the nitrogen series samples grown with a similar fabrication method is disclosed herein.

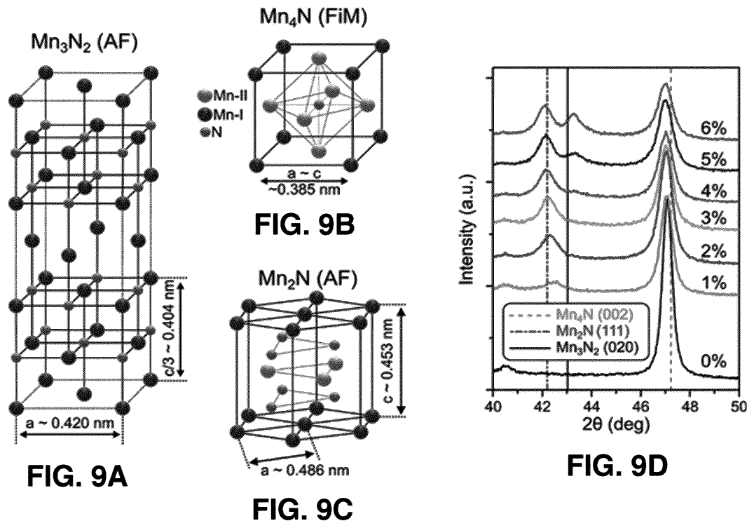

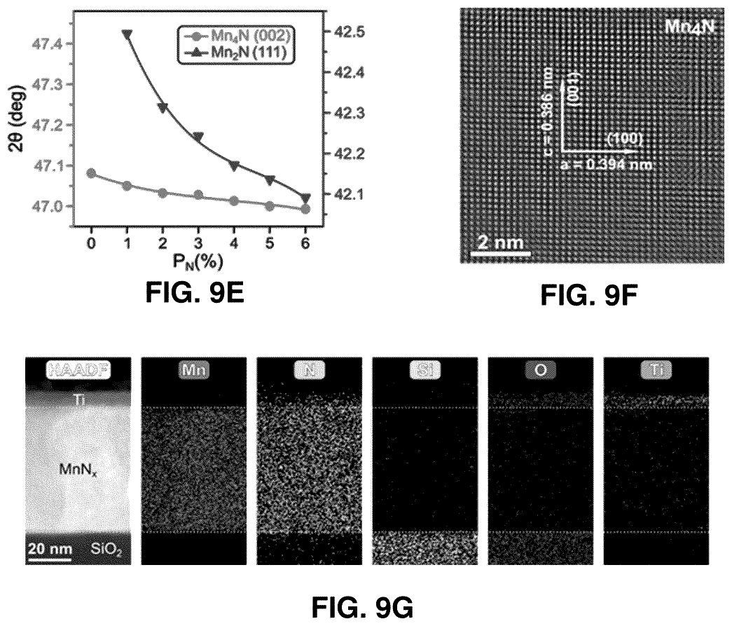

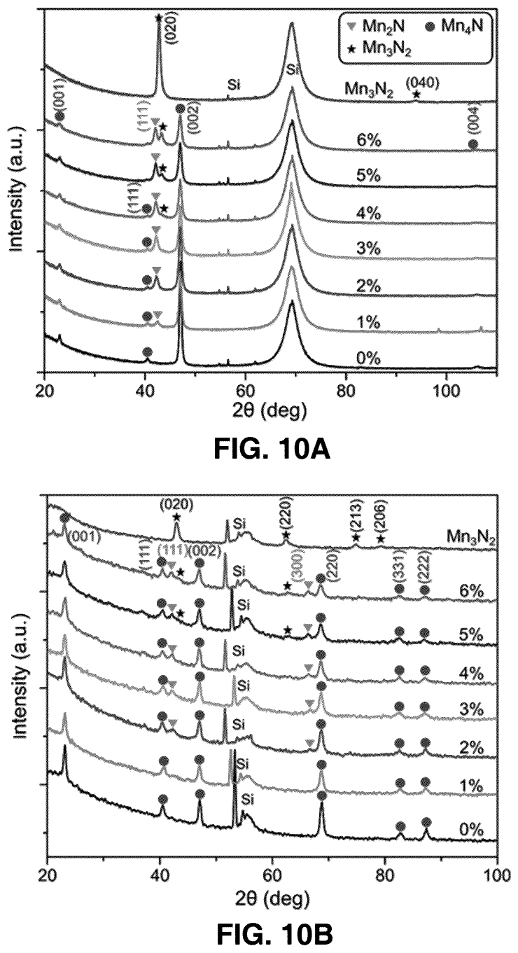

The Mn₃N₂ is again used as a seed layer that provides the crystalline texture and nitrogen needed for Mn₄N growth. FIGS. 9a-9g show structural characterizations for the nitrogen series. FIG. 9a shows a schematic illustrating a lattice structure of Mn₃N₂. FIG. 9b shows a schematic illustrating a lattice structure of Mn₄N. It's an AF with a high Neel temperature (T_{N}˜925 K). Mn₃N₂ can lose nitrogen easily and transform into the Mn₂N phase, which has a hexagonal structure and is also an AF with T_{N}˜300 K. FIG. 9c shows a schematic illustrating a lattice structure of Mn₂N. To start, 20 nm of Mn₃N₂ seed layer is deposited on Si substrate, where XRD scans have confirmed the successful growth of this layer. FIGS. 10a and 10b show two graphs illustrating full range 2θ-ω and grazing incidence X-ray scans for the nitrogen series with P_{N} from 0% to 6% labeled next each curve, and a single Mn₃N₂ seed layer. P_{N} is the nitrogen partial pressure during Mn deposition on top of 20 nm Mn₃N₂ seed layers. Subsequently, 40 nm of Mn is deposited onto this seed layer with zero nitrogen partial pressure (P_{N}=0%). FIG. 9d shows XRD 2θ-ω scans showing the phase evolution of the P_{N} series samples with Mn₃N₂ (20 nm)/Mn (40 nm) as the starting layer structures fabricated with different P_{N}, where P_{N} is the nitrogen partial pressure during the Mn deposition. Vertical lines show the expected peak locations of Mn₄N (002) (red), Mn₂N (111) (blue), and Mn₃N₂ (020) (black). As shown in FIG. 9d, a Mn₄N single-phase film was formed, where one prominent peak around 47.10 shows up. This Mn₄N single phase is also confirmed by the grazing incidence XRD scan and the full range 2θ-ω scan in FIGS. 10a and 10b. The P_{N} may then be increased during Mn deposition while fixing other deposition parameters, equivalent to adding more nitrogen into this Mn₄N single phase. A peak near 42.2° shows up and grows larger. This peak is the (111) diffraction from the ξ-phase Mn₂N, which has thermal stability and nitrogen content between η-Mn₃N₂ and ε-Mn₄N. Eventually, as P_{N} reaches 4%, the Mn₃N₂ (020) peak shows up and grows bigger, indicating some of the Mn₃N₂ phase in the seed layer was recovered. These results show that through increasing P_{N} during Mn deposition, the layers can be transformed continuously from Mn₄N single phase into Mn₄N/Mn₂N, and then to Mn₄N/Mn₂N/Mn₃N₂. Grazing incidence XRD also shows the same phase transformations as FIG. 9d, along with full range gonio scans shown in FIG. 10a.

The films' nitrogen concentration and phase evolution can be clearly shown by investigating the XRD peak position variations. Mn Nitride lattice parameters are known to be very susceptible to nitrogen content, where the interstitial nitrogen usually causes the lattice to expand, and nitrogen vacancies would do the opposite. FIG. 9e shows trends showing Mn₄N (002) (red) and Mn₂N (111) (blue) peak location (extracted from FIG. 9d) variations as P_{N} changes. Solid lines are guides to the eye. As shown in FIG. 9e, Mn₄N and Mn₂N peaks both shift to lower angles as P_{N} increases, consistent with the fact that more nitrogen is being incorporated into their lattices. To study the crystalline quality, scanning transmission electron microscopy (STEM) was performed on the P_{N}=0% sample. Highly ordered cubic Mn₄N crystal can be clearly seen in FIG. 9f. A small in-plane tensile strain from the STEM image may be identified, with a=0.394 nm and c=0.386 nm, which agrees with the observed out-of-plane Mn₄N (002) peak location at 2θ=47.1°. This tetragonal lattice distortion is also believed to be the origin of the perpendicular magnetic anisotropy in Mn₄N thin films. Shown in FIG. 9g, the high-angle annular dark-field (HAADF) STEM image and the energy-dispersive X-ray spectroscopy (EDX) elemental maps of the sample cross-section are obtained from the same P_{N}=0% sample. These images again demonstrated high quality films with homogeneous distribution of Mn and N inside the Mn nitride layer, while nitrogen tends to move into the capping layer due to its high mobility and Ta's affinity for nitrogen.

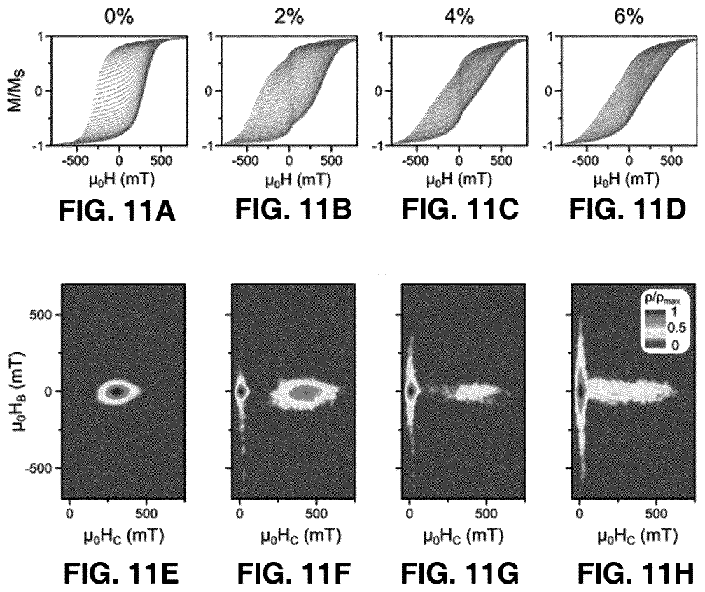

First order reversal curves (FORCs) were taken on the P_{N}=0%, 2%, 4%, and 6% samples in the nitrogen series with OP magnetic field at room temperature. As shown in FIG. 11a, the 0% FORCs exhibit a square hysteresis with each FORC returning to positive saturation in a generally horizontal way. The corresponding FORC distribution shows one prominent feature at μ₀H_{C}=300 mT (FIG. 11e), which indicates a high anisotropy phase with perpendicular magnetic anisotropy.

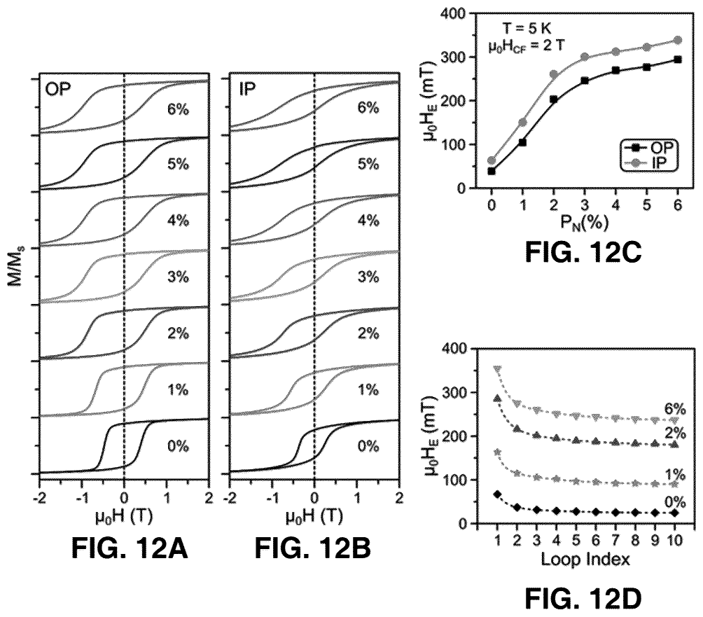

FIGS. 12a and 12d illustrate hysteresis loops and training effect for the nitrogen series. Hysteresis loops were measured at 5 K after cooling from room temperature with out-of-plane (OP) and in-plane (IP) positive 2 T magnetic field. A clear shift of the hysteresis loops to the negative field direction can be seen in both the OP and IP loops (FIGS. 12a and 12b, respectively). Moreover, the OP loops are wider and squarer than the IP loop, consistent with the perpendicular magnetic anisotropy (PMA) reported in Mn₄N films.

The trend of exchange field (μ₀H_{E}) variation becomes evident when plotted in FIG. 12c, where both IP and OP μ₀H_{E} increase monotonically as the P_{N} increases from 0% to 6%. Notably, there is a rapid ascent from 0% to 2%, followed by a more gradual incline from 3% to 6%. This observed trend can be directly associated with the phase transitions identified in the XRD data as shown in FIG. 9d, which shows that the antiferromagnetic Mn₂N peak evolves from unnoticeable (0%) to prominent (2%). This peak then stays relatively the same from 3% to 6% while another Mn₃N₂ peak emerges and grows larger. The exchange bias has been previously mainly attributed to the interaction between FiM Mn₄N and AF Mn₂N. Mn₃N₂, despite being AF as well, is not believed to contribute to the exchange bias significantly, as the field cooling was done well below its rather high T_{N}.

The field training effect for the exchange bias was also investigated. Samples from the nitrogen series were initially field cooled from 380 K to 5 K in a 2 T IP field before ten consecutive hysteresis loops were taken. μ₀H_{E} were then extracted from the ten loops and plotted in FIG. 12d. μ₀H_{E} shows an exponential decay that's typical for exchange bias systems, which can be fitted with the following model considering both the rotatable and frozen spins near the interfaces

$${H}_{E}^{n} = {H}_{E}^{∞} + {A}_{F} exp ( - \frac{n}{{P}_{F}} ) + {A}_{R} exp ( - \frac{n}{{P}_{R}} ) ,$$

where n is the loop number, and H_{E}ⁿ is the exchange field of the nth loop, A_{F} and A_{R} are parameters with magnetic field units that are related to the frozen and rotatable spins, respectively. P_{F} and P_{R}, on the other hand, are dimensionless parameters that resemble relaxation times for the frozen and rotatable spins, respectively. The fitted curves are the dotted lines in FIG. 12d. Notably, the frozen spins are found to relax seven times slower than the rotatable ones, consistent with the findings from other studies. Moreover, the remarkable tunability of the exchange bias is manifested in the ten-fold increase of

$${H}_{E}^{∞} , from {H}_{E}^{∞} = 23 mT for the {P}_{N} = 0 \%$$

sample to 234 mT for the P_{N}=6% sample.

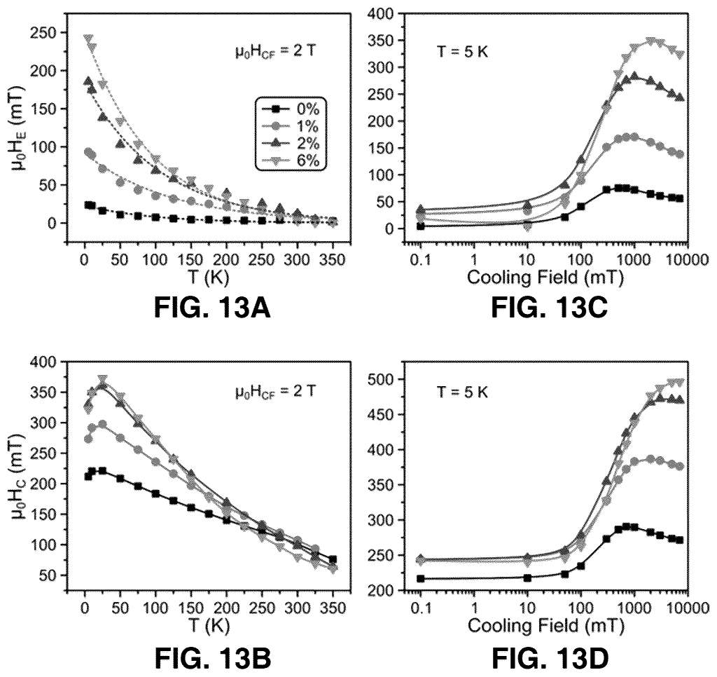

To further elucidate the origin of the exchange bias effect, its temperature dependence may be studied. Samples were initially field cooled from 380 K to 5 K in a positive 2 T IP magnetic field and field trained with ten hysteresis loops. Afterward, a hysteresis loop was recorded at each temperature step as it warms back to 350K. μ₀H_{E} was extracted and plotted as a function of temperature for samples with different P_{N}, as shown in FIG. 13a. μ₀H_{E} monotonically decreases in all samples and vanishes around 325 K. μ₀H_{E} may be further fit using the following exponential function,

$${H}_{E} ( T ) = {H}_{E}^{0} * exp ( - \frac{T}{τ} ) ,$$

where H_{E}⁰ is the extrapolation of H_{E} to absolute zero temperature and τ is a constant. This exponential temperature-dependent decay of H_{E} has been observed in systems with frustrated spins caused by competing magnetic interactions. Moreover, in the temperature-dependent μ₀H_{C}=curve (FIG. 13b), a small peak at low temperature can be seen across the samples. This peak in μ₀H_{C} is normally associated with rotatable AF spins or glassy spins. Below the temperature where the peak shows up, the AF spins are completely frozen and lead to reduced coercivity. Upon close examination, the peak in μ₀H_{C}=also shows up at higher temperatures with increasing P_{N}, from 18 K for P_{N}=0%, 21 K for 1%, 22 K for 2%, to 26 K for 6% sample. This trend indicates that the Mn nitride systems have more glassy spins as the nitrogen concentration increases.

This interpretation is further corroborated by examining the exchange bias with different cooling fields. Samples were first demagnetized at room temperature and then cooled down to 5 K in a positive IP magnetic field (cooling field). As shown in FIG. 13c, the exchange fields (μ₀H_{E}) rises rapidly and peaks before decreasing slowly as the cooling field increases. This behavior in μ₀H_{E} is again often associated with exchange bias systems containing glassy spins. The initial increase in μ₀H_{E} as the cooling fields increase is due to an increased FiM alignment. However, as the cooling field gets even larger, Zeeman energy is significant enough to compete with the frustrated exchange interaction which leads to glassy spins. As the glassy spin in the system gets reduced due to a better alignment with the large magnetic fields, its contribution to the exchange bias gets reduced. The fields at which μ₀H_{E} peaks also increase monotonically as P_{N} increases from 0.6 T for P_{N}=0%, 0.8 T for 1%, 1 T for 2%, to 2.2 T for 6%, indicating the higher P_{N} sample contains more glassy spins which requires larger field to align. This is consistent with the previous interpretation about the μ₀H_{C}=maxima (FIG. 13b). Moreover, the cooling field dependence of μ₀H_{C}=shows a similar trend as the μ₀H_{E}, where the peak field gets pushed to high fields for samples with higher nitrogen concentrations (FIG. 13d).

### Third Embodiment (Annealing Series)

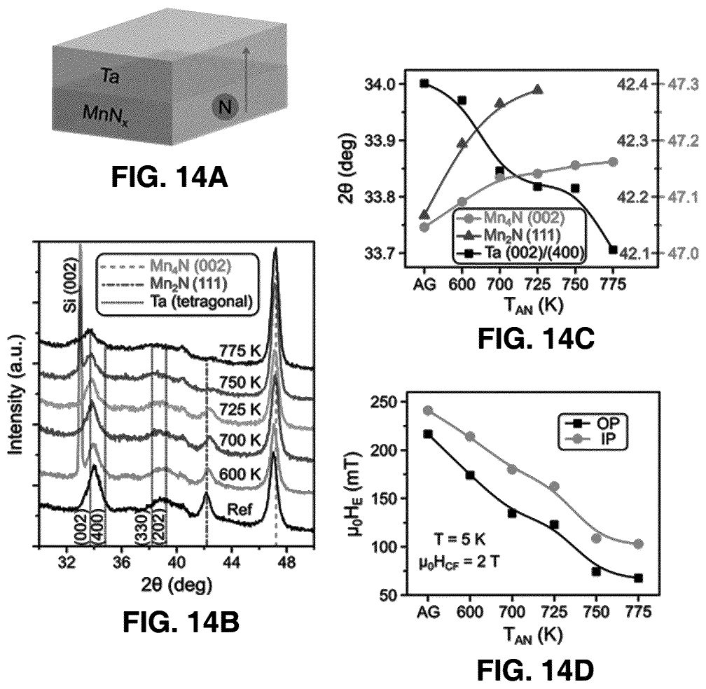

It is shown that the exchange bias in the Mn₄N system can increase by over an order of magnitude through adding nitrogen during the fabrication process in the nitrogen series. Another embodiment shows the magnetic properties in similar Mn₄N system can be controlled through post-annealing magneto-ionic effects. It should be noted that samples used in the post-annealing process were grown at the same time and have the same layer structure, which is the same structure as the P_{N}=6% sample in the nitrogen series, except that they are capped with a 50 nm Ta layer instead of 5 nm Ti. Through its affinity for nitrogen, the thicker Ta layer acts as a nitrogen “getter” material, which draws and stores nitrogen from the Mn nitride layers. Schematics in FIG. 14a show the sample layer structure and the expected direction of nitrogen motion when annealed. As shown in FIG. 14b, Mn₄N, Mn₂N, and Ta peaks can be seen in the reference (Ref) sample which has not been through thermal treatment after growth. Interestingly, when compared with the P_{N}=6% sample shown in FIG. 9d, the Mn₃N₂ peak is missing in the Ref sample. This is likely caused by Ta's strong affinity to nitrogen. Even though Ta is deposited at room temperature, it still spontaneously reacts with nitrogen and disrupts Mn₃N₂ structure, similar to the redox reactions that occur in oxide systems with Gd.

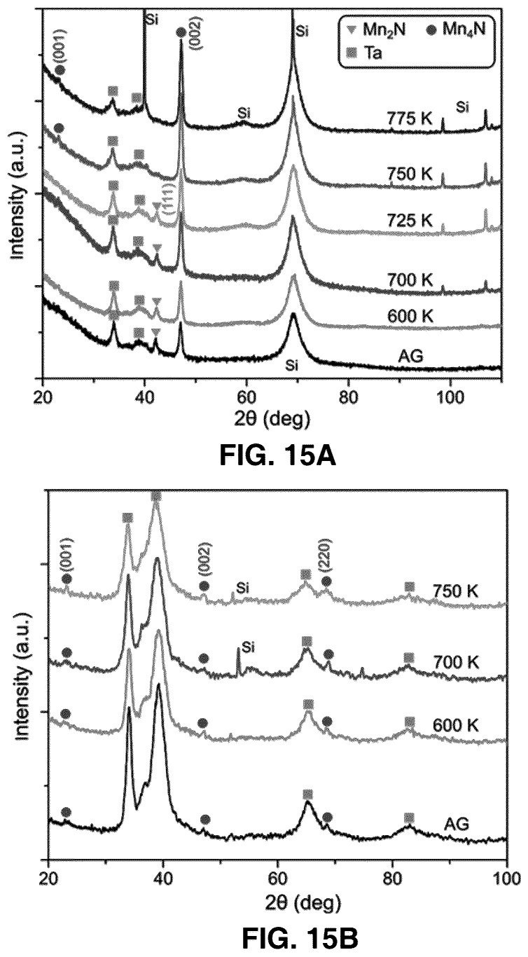

Individual samples cleaved from the same film as the Ref sample were then annealed in vacuum for 1 min at different annealing temperatures (T_{AN}), referred to here as the “annealing series”. As T_{AN} increases, the Mn₂N peak has the most noticeable change as it shifts to higher angles and eventually disappears at T_{AN}=775 K (FIG. 14b). Interestingly, Ta peaks seem to simultaneously shift to the lower angles and get broader with increasing temperature. The evolution of the different phases becomes more evident when their peak locations are plotted in FIG. 14c. Mn₂N and Mn₄N peaks both shift to higher angles as their lattice contracts after losing nitrogen to Ta. This process transforms the starting Mn₄N/Mn₂N layers back to the Mn₄N single phase, opposite to the effect of increasing P_{N} shown in FIG. 9d. Moreover, the Ta peaks shift to lower angles after absorbing the nitrogen from the nitride phases which causes its lattice to expand. These interpretations are consistent with the full range 2θ-ω and grazing incidence scans in FIGS. 15a and 15b.

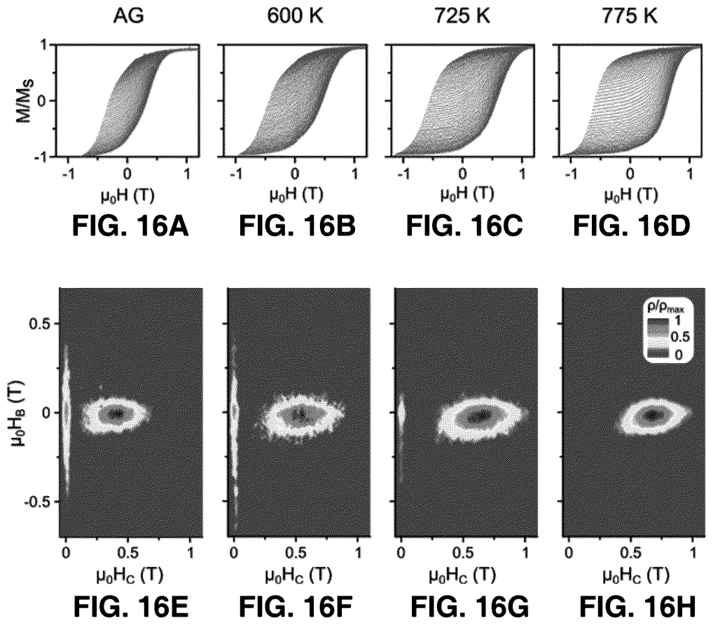

To study the exchange bias, samples from the annealing series are field cooled from 300 K to 5 K with a positive 2 T magnetic field. As T_{AN} increases, both OP and IP μ₀H_{E}ⁿ decreases monotonically from 217 to 68 mT and 241 to 103 mT, respectively (FIG. 14d). The decrease of exchange bias is consistent with the reduction of the AF phase, Mn₂N, as nitrogen moves into the Ta layer with annealing and the corresponding increase in the FiM Mn₄N phase. These results demonstrate that the exchange bias in all Mn nitride system can be controlled by driving nitrogen into a neighboring Ta layer with post-annealing. Room temperature magnetic reversal behaviors of the annealing series was studied using FORC in FIG. 16, which shows the softer magnetic phase vanishing as nitrogen is removed from the Mn nitrides through annealing, consistent with the formation of more Mn₄N phase.

### Fourth Embodiment (Gating Series)

It is shown that the exchange bias in the Mn₄N system can be reduced through driving nitrogen out of nitride layers and into an adjacent Ta layer in the annealing series. The final and fourth embodiment shows the magnetic properties in a similar Mn₄N system can be controlled through voltage-induced ionic motion.

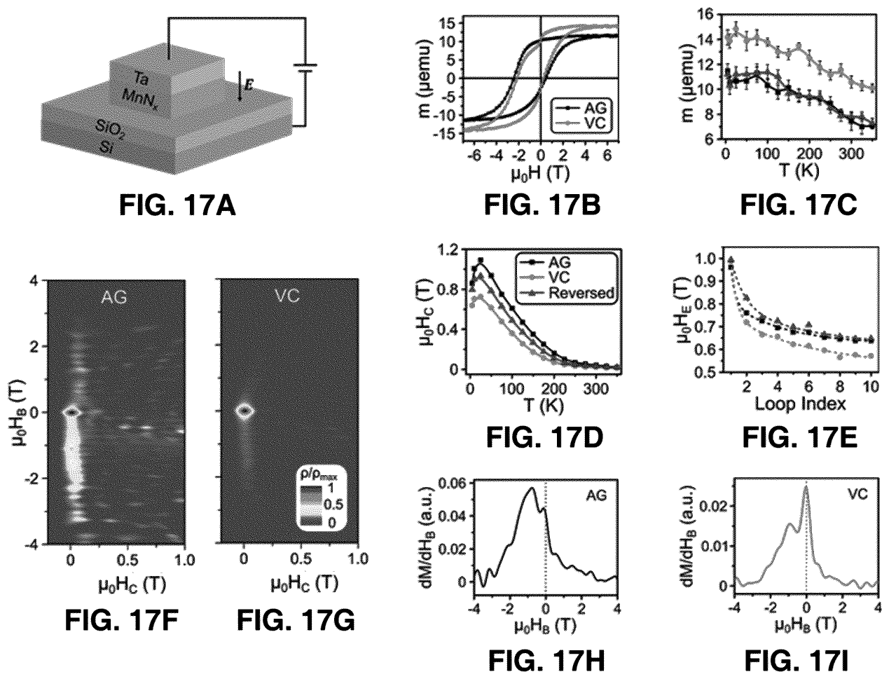

Shown in FIG. 17a, MnNₓ (15 nm)/Ta (10 nm) are deposited onto Si substrate with thermally oxidized SiO₂. The MnNₓ layers are composed of a 5 nm Mn₃N₂ seed layer and 10 nm of Mn deposited with P_{N}=6%, keeping similar ratios between layers as the annealed series samples (and the MnNₓ layer of the nitrogen series samples). The top electrical contact is made to the Ta layer, while the bottom contact is made to the p-type Si substrate. With this geometry, an electric field pointing from the top Ta to the bottom Si is established with positive voltage as shown in FIG. 17a. Shown in FIG. 17b, there is a noticeable difference in the hysteresis loops of the sample in the as-grown (AG) state and the voltage-conditioned (VC) state that was gated with +30 V for 1 hour at room temperature. Note the hysteresis loops are measured on the same sample at 5 K right after positive 2 T field cooling before and after voltage conditioning. Closer examinations reveal an increase in the M_{S} by 23% and a decrease in coercivity (9%) and exchange bias (2%). In the meantime, an intriguing kink near remanence shows up on the VC state hysteresis. The increase in the M_{S} indicates more magnetic (ferrimagnetic or ferromagnetic) material has formed during voltage conditioning. The annealing series demonstrated that more ferrimagnetic Mn₄N can be formed by pulling nitrogen out of the Mn nitrides (FIG. 14), and here, positive voltage conditioning is expected to drive nitrogen out of the Mn nitride and into the Ta layer, suggesting more Mn₄N has formed during voltage conditioning.

The temperature dependence of the M_{S}, shown in FIG. 17c, may be studied further. The magnetic moment is consistently larger in the VC state by 3 to 4 emu compared to the AG state of each sample from 5 to 350 K. This change is well above the measurement error (<1 emu), and again suggests that the increase in magnetization is from the increased amount of Mn₄N with a high Curie temperature around 745 K. Samples in the VC state were then gated with −45 V for three hours to drive nitrogen back into the nitrides (reversed state). Interestingly, the blue curve in FIG. 17c indicates the M_{S} of the reversed state was reduced to similar values as the AG sample, suggesting the voltage induced change in M_{S} is reversable.

The temperature dependence of the coercivity is also plotted in FIG. 17d, where it is seen that VC state coercivity is considerably smaller than the AG state of the sample at all temperatures, likely because there is less coercivity enhancement effect as the exchange bias gets smaller. Interestingly, the coercivities first peak at some lower temperatures and then decrease as temperature increases, similar to the results on the nitrogen series samples shown in the supplementary materials FIG. 13. These peaks indicate the existence of glassy spins, which are frozen and don't contribute to the coercivity as much below the temperature that the coercivities peak. The peak locations also shift after the sample was gated. For the AG sample, the coercivity peak is located at 23.7 K, while the VC state peak is located at 19.8 K. This indicates that voltage conditioning can reduce spin frustration. Again, similar trend is also present in supplementary materials FIG. 13, that is, the temperatures where coercivities peak are larger for higher nitrogen concentration samples. For the reversed sample, the coercivity does increase compared to the VC state, however, it didn't increase to the same level as the AG state, suggesting some voltage induced changes such as film structure changes are irreversible, which were also seen in other magneto-ionic systems.

To further confirm the voltage-induced change in the exchange bias, the training effect on the AG, VC, and reversed states may be measured, where ten consecutive loops were taken after field cooling from 380 K. As shown in FIG. 17e, there is little difference in the exchange field for the first loops. Interestingly, the gap between AG and VC exchange fields gets wider after each loop. After fitting, the equilibrium exchange fields (H_{E}^{∞}) are 622 mT and 525 mT for the AG and VC state, respectively. A decrease in exchange bias by 16% after gating. For the reversed state, H_{E}^{∞} increases back to 613 mT, which is similar to the value of the AG state. These results show the exchange bias can also be manipulated by voltage reversibly.

Furthermore, FORC maybe measured with in-plane fields at 5 K after field cooling and field training. FORC is known as a powerful characterization technique that can disentangle different magnetic interactions and provides insights that are not attenable with regular hysteresis loops. As mentioned in the disclosure, FORC was measured to map out the trend of Mn₄N phase evolution as nitrogen was added or taken away from the Mn nitrides (supplementary materials FIGS. 11 and 16). Here, FORC may be utilized to highlight the voltage-induced changes in magnetic properties. The FORC distribution for the AG state (FIG. 17f) displays a prominent vertical ridge feature that's located along the μ₀H_{C}=0 axis. Closer examinations reveal a sharp peak feature centered around the origin. This feature is typically associated with magnetically soft particles which reverses via single domain rotation. This suggest some parts of film are not exchange biased likely due to the small size of the magnetic clusters. Besides the peak, there is also a large spread along the μ₀H_{B} axis. This vertical spread is mainly located in the negative μ₀H_{B} axis, which is characteristic of an exchange bias system. This is consistent with the major hysteresis loops that shows the sample is exchange-biased to the negative field direction. Interestingly, the VC state FORC distribution is drastically different from that of the AG state (FIG. 17g). All the features are still along the μ₀H_{C}=0 axis but the spread has now been reduced. And the feature near origin now dominates the signal. These suggest that the exchange bias has been reduced by gating which is also consistent with the results shown in FIG. 17e. Moreover, the growth of the feature near origin can also be associated with the kink near remanence in the hysteresis loop for the VC state (FIG. 17b). This is because that the Mn₄N formed through voltage induced nitrogen motion likely exist as small clusters, which would contribute to the softer phase that switches near remanence. Similar voltage induced changes were also observed in another CoₓMn₁₋ₓN system. Moreover, these changes can be highlighted by the bias field distribution plots in FIGS. 17h and 17i, which are done by projecting the FORC distribution onto the μ₀H_{B} axis through integrating along the μ₀H_{C}=axis. Both plots are asymmetric around the μ₀H_{B}=0, indicating the samples are both exchange biased. Nevertheless, the AG state has a much more pronounced peak around μ₀H_{B}=−1 T than the VC state, indicating larger exchange bias. On the other hand, the peak around μ₀H_{B}=0 in the VC state gets larger after gating, indicating the increase of magnetic regions that are not exchange-biased. These changes are also consistent with the interpretation that the exchange bias is reduced through voltage induced nitrogen ionic motion which causes the formation of more ferrimagnetic Mn₄N likely from the AF Mn₂N.

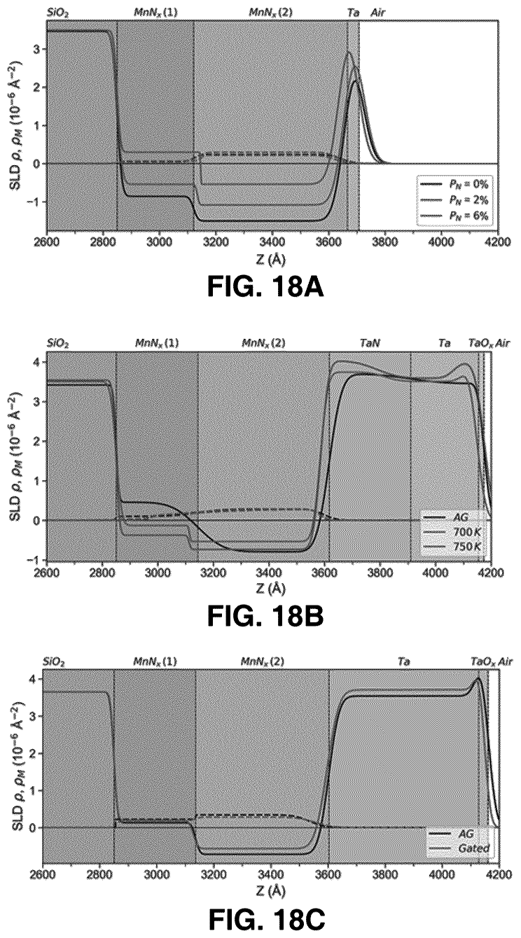

To gain deeper understanding of the nitrogen ionic motion within the thin film heterostructures, PNR experiments may be conducted on samples from the nitrogen, annealing and gating series, shown in FIG. 18. The sensitivity of PNR benefits from the scattering length density (SLD) contrast that is produced by small variations in nitrogen concentrations in MnNₓ,²⁶ as Mn has a negative nuclear SLD (β_{N}) (β_{N,Mn}=−2.98×10⁻⁶ Å⁻² [1 Å 10⁻¹⁰ m]) and as nitrogen concentration increases ρ_{N} increases continuously, with the other MnNₓ phases having ρ_{N,Mn}_{₄}=−0.89×10⁻⁶ Å⁻², ρ_{N,Mn}_{₂}_{N}=0.62×10⁻⁶ Å⁻², and ρ_{N,Mn}_{₃}_{N}_{₂}=1.38×10⁻⁶ Å⁻². This allows for more accurate identification of the expected MnNₓ phases as a function of depth, normal to the substrate, and the nitrogen ionic motion within the heterostructures.

The Mn nitride layers in all eight samples can be best fit with a two-layer model, where each layer's thickness is comparable to the nominal thickness of the Mn₃N₂ seed layer (27 nm) and Mn layer (51 nm) deposited with various nitrogen partial pressure. Note that the samples used for the neutron experiments are thicker and were grown separately from the samples used for magnetometry and XRD studies. For the nitrogen series samples (FIG. 18a), the bottom MnNₓ (1) layer in the ρ_{N}=0% sample is modeled with ρ_{N}=−0.87×10⁻⁶ Å⁻², which varies significantly from the expected value for the as grown Mn₃N₂. Additionally, the top MnNₓ (2) layer, despite being deposited in a pure Ar environment, has a much larger ρ_{N} (−1.50×10⁻⁶ Å⁻²) than the expected value for Mn. The differences from the expected ρ_{N} in the MnNₓ layers is consistent with the as deposited Mn (MnNₓ (2) layer) acquiring nitrogen from the bottom Mn₃N₂ (MnNₓ (1) layer) during growth to form Mn₄N and nitrogen deficient Mn₄N, respectively. As P_{N} is increased to 2% and 6%, the bottom MnNₓ (1) layer's ρ_{N} increases significantly to −0.54×10⁻⁶ Å⁻² and 0.29×10⁻⁶ Å⁻², respectively, which may represent Mn₄N mixed with an increasing amount of Mn₂N. The top MnNₓ (2) layer ρ_{N} also increases to −1.09×10⁻⁶ Å⁻² (P_{N}=2%) and −0.54×10⁻⁶ Å⁻² (P_{N}=6%), representative of Mn₄N and mixed phases of Mn₄N and Mn₂N, respectively. This is consistent with the trends seen in the XRD and magnetometry results. The Ta layer ρ_{N} increases up to P_{N}=6% (6.31×10⁻⁶ Å⁻²), varying from the expected ρ_{N} of Ta (3.83×10⁻⁶ Å⁻²), and is likely caused by more nitrogen moving into the Ta layer as P_{N} increases, along with oxidation. These changes in ρ_{N} are all statistically significant as the 95% confidence intervals (CI) of the modeled ρ_{N} have no overlap. Unlike the ρ_{N}, the change in the magnetic SLD (ρ_{M}) are less conclusive between the samples, which could be attributed to the small M_{S} (<85 emu/cc) and small variation (<25%) in Mₛ when P_{N} is varied. Nevertheless, a constantly larger ρ_{M} is seen in the top MnNₓ (2) layer compared to the bottom MnNx (1) layer within each of the nitrogen series samples. This suggests that most of magnetic signal is coming from the MnNₓ (2) layer that was deposited onto the Mn₃N₂ seed layer.

The PNR results of the annealing series are summarized in FIG. 18b. Note that the annealing series has a thicker Ta layer (50 nm) on top for nitrogen storage. The reference sample in the annealing series is the as-grown (AG) sample, which is grown with a P_{N}=6%. The annealed samples were all cut out from the same reference sample. The MnNₓ layers have ρ_{N} that are comparable with the 6% sample in the nitrogen series, which is expected given that they have the same growth condition. After the annealing at 700 K for 1 min, the ρ_{N} for MnNₓ (1) dropped considerably from 0.47×10⁻⁶ Å⁻² to −0.11×10⁻⁶ Å⁻², while the MnNₓ (2) ρ_{N} increased slightly from −0.81×10⁻⁶ Å⁻² to −0.55×10⁻⁶ Å⁻². When annealed at 750 K, the decrease in ρ_{N} becomes larger in the MnNₓ layers, with the bottom and top decreasing to −0.38×10⁻⁶ Å⁻² and −0.74×10⁻⁶ Å⁻², respectively. The Ta layer in all three conditions (AG, 700 K, 750 K) is best modeled with three sublayers that are referred to as TaNₓ, Ta, and TaOₓ in FIG. 18b. From the AG state, the TaNₓ layer has an increase in ρ_{N} with increasing temperature (3.67×10⁻⁶ Å⁻² to 4.03×10⁻⁶ Å⁻²). This, along with the decreasing ρ_{N} in MnNₓ (1), is consistent with an increasing amount of nitrogen moving out of the MnNₓ and into the Ta layer with increasing temperature. The initial increase in ρ_{N} for MnNₓ (2) at 700 K is thought to be caused by an initial redistribution of nitrogen, as this layer continues to pull nitrogen from the MnNₓ (1) layer. The subsequent decrease at 750 K may be due to the increased nitrogen diffusion caused by Ta and/or the smaller amount of nitrogen available to MnNₓ (2) from MnNₓ (1). TaOₓ is indicated in each condition with an increase in ρ_{N} at the surface of the sample, likely caused by oxygen presence in the annealing chamber or from exposure to air. It should be noted that the apparent decrease in MnNₓ total thickness and increase in total Ta thickness is consistent with nitrogen moving out of MnNₓ and into Ta, but the change is not statistically significant in the models.

In the gating series, PNR measurements were done on two samples from this series, one control sample (AG) and one sample gated with +30 V. Note the gating series samples used for neutron measurements are thicker than the ones shown in FIG. 17. The best model that fits the two samples are very similar, shown in FIG. 18c, which suggests the nitrogen motion that's induced by voltage is less significant compared to that in the nitrogen and annealing series. Nevertheless, statistically significant changes can be identified by careful inspections of the ρ_{N} variation. It should also be noted that the AG state has comparable model parameters to the nitrogen ρ_{N}=6% and annealed series AG samples since they have similar growth parameters. The bottom MnNₓ (1) ρ_{N} for both gated series samples are similar, and statistically significant differences between them cannot be determined as their 95% CI largely overlap. On the other hand, the top MnNₓ (2) variation reaches statistical significance, with an increased in ρ_{N} after gating (ρ_{N,AG}−0.72×10⁻⁶ Å⁻²; ρ_{N,VC}=−0.58×10⁻⁶ Å⁻²), suggesting nitrogen has moved into this layer from the MnNₓ (1). The Ta layer also has a statistically significant increase in ρ_{N} after voltage conditioning (ρ_{N,AG}=3.54×10⁻⁶ Å⁻²; ρ_{N,VC}=3.71×10⁻⁶ Å⁻²). Considering these factors, it can be speculated that nitrogen has moved into the top MnNₓ (2) and Ta layer from the bottom nitrogen rich MnNₓ (1) layer after applying voltage, as it is the only available source of nitrogen and is consistent with the expected nitrogen ion motion with positive voltage gating.

The methods disclosed herein result in an all Mn nitride system with highly tunable magnetic properties. This all-nitride system can be first grown with the ionically driven synthesis method. By modulating the nitrogen content through adjustments in nitrogen partial pressure during deposition and thermal-induced nitrogen motion facilitated by an adjacent tantalum layer, significant tunability in the exchange bias effect can be achieved. Specifically, the exchange bias can be increased by over an order of magnitude and reduced by over 70% by adding and removing nitrogen, respectively. XRD, TEM, and magnetometry studies confirmed the phase transformations from a single-phase Mn₄N to mixed phase Mn₄N/Mn₂N and Mn₄N/Mn₂N/Mn₃N₂ with nitrogen addition, and the reverse transformation with nitrogen removal. Furthermore, reversibly voltage-induced nitrogen ionic motion is demonstrated, resulting in a 23% change in saturation magnetization and a 15% change in exchange bias at 5 K. These nitrogen ionic motions are further corroborated by the polarized neutron reflectivity results. The demonstrated tunability of magnetic properties through deposition, post-annealing, and voltage conditioning paves the way for energy-efficient and environmentally friendly spintronic devices.

The current material system also offers an all-nitride platform to continuously tune the materials properties, for example, from antiferromagnetic (AF) to ferrimagnetic (FiM). Thus the nitride heterostructure can be dialed up to be AF only, or AF/FiM, or FiM only, and their physical properties (particularly magnetic properties) can be tuned easily, for example via synthesis conditions or external stimuli such as an electric field.

One of the key advantages of the ionically driven synthesis method is substrate compatibility. Specifically, the method does not require specific substrates such as SrTiO₃ or MgO, which are commonly used in existing fabrication methods. Instead, it can be applied to a wide range of amorphous substrates as is demonstrated herein using Si substrate with an amorphous SiO₂ layer. This is a crucial advantage as it aligns with the current Complementary Metal-Oxide-Semiconductor (CMOS) processes widely used in the semiconductor industry. It simplifies the integration of Mn₄N films into existing semiconductor manufacturing workflows, potentially reducing production costs and making it more accessible for commercial applications. Unlike existing methods that demand precise control of the nitrogen environment during deposition, the ionically driven synthesis method leverages an Mn₃N₂ seed layer, which is relatively easy to grow, thereby providing nitrogen environment simplification. The Mn₄N phase is achieved by depositing Mn in a nitrogen-free environment. This simplification reduces the instrument-to-instrument variability seen in other methods, making scalable production possible.

The Mn₄N films can also be potentially integrated into existing spintronic devices such as MRAM, magnetic storage, and magnetic sensors, making them more sustainable. Moreover, it may offer transformative technologies such as neuromorphic computing through its magneto-ionic properties. The advantages of the ionically driven synthesis method for Mn₄N thin films over existing fabrication methods are significant and have the potential to revolutionize the way these materials are produced.

What is claimed is:

1. A method of fabricating a magnetic material comprising:
reactively sputtering a Mn₃N₂ seed layer onto a substrate at a first temperature;
annealing the Mn₃N₂ seed layer at the first temperature;
depositing a Mn layer onto the Mn₃N₂ seed layer at the first temperature, wherein the substrate, Mn₃N₂ seed layer, and deposited Mn layer form a sample;
cooling the sample to a second temperature lower than the first temperature; and
depositing a capping layer onto the sample to form the magnetic material.

2. The method of claim 1, wherein the substrate is a Si substrate having a SiO₂ layer.

3. The method of claim 1, wherein the Mn₃N₂ seed layers are reactively sputtered onto the substrate.

4. The method of claim 1, wherein the first temperature is approximately 450° C.

5. The method of claim 1, wherein the reactively sputtering the Mn₃N₂ seed layer is performed in a vacuum chamber at about 5 mTorr sputtering pressure with 1 to 1 Ar to N₂ ratio.

6. The method of claim 1, wherein the annealing is vacuum annealing.

7. The method of claim 1, wherein cooling the sample comprises cooling the sample to approximately room temperature.

8. The method of claim 1, wherein the thickness of the Mn layer can be varied to form either a single Mn₄N layer or multilayers of Mn₄N/Mn₂N or multilayers of Mn₄N/Mn₂N/Mn₃N₂.

9. The method of claim 1, wherein the resulting magnetic material exhibits an exchange bias that can be varied by over an order of magnitude by adjusting nitrogen partial pressure during deposition of the Mn layer.

10. The method of claim 9, wherein the Mn layer is deposited using with nitrogen partial pressures (P_{N}) varying from 0% to 6%, where P_{N}=N₂ flow rate/Ar+N₂ flow rate×100%.

11. The method of claim 9, wherein the magnetic material goes through a transformation from Mn₄N to Mn₄N/Mn₂N and Mn₄N/Mn₂N/Mn₃N₂ mixed phases when nitrogen partial pressure is increased.

12. The method of claim 1, further comprising a post-annealing process that reduces the exchange bias by up to 70% by driving nitrogen out of the Mn nitride layer into a neighboring tantalum (Ta) layer.

13. The method of claim 12, wherein the Mn layer is deposited using a fixed 6% nitrogen partial pressures (P_{N}).

14. The method of claim 12, wherein the capping layer is a Ta capping layer.

15. The method of claim 12, wherein the magnetic material goes through a transformation from Mn₄N/Mn₂N mixed phase to Mn₄N single phases when nitrogen is removed from the nitride layer during post annealing.

16. The method of claim 1, further comprising applying a positive voltage across the Mn nitride layers to drive nitrogen ions out of the Mn nitride layers and into the neighboring Ta layer, resulting in an increase in saturation magnetization and a decrease in exchange bias.

17. The method of claim 16, wherein the Mn layer is deposited using a fixed 6% nitrogen partial pressures (P_{N}).

18. The method of claim 16, wherein the capping layer is a Ta capping layer.

19. The method of claim 16, wherein the changes induced by positive voltage conditioning are reversed upon applying a negative voltage conditioning, driving nitrogen ions back into the Mn nitride layers.

20. The method of claim 1, further comprising a Ta layer to receive nitrogen ions during post-annealing and voltage application, enabling controlled manipulation of magnetic phases.

21. The method of claim 1, wherein the fabrication process is adaptable for creating other ionic systems, including oxides, borides, and lithium-based materials.

22. A magnetic material fabricated by the method of claim 1, comprising:
a substrate;
a Mn₃N₂ seed layer reactively sputtering annealing onto the substrate at a first temperature;
a Mn layer deposited onto the Mn₃N₂ seed layer at the first temperature, wherein the substrate, Mn₃N₂ seed layer, and deposited Mn layer form a sample; and
a capping layer deposited onto the sample to form the magnetic material, wherein the material exhibits a tunable exchange bias and saturation magnetization and perpendicular magnetic anisotropy for spintronic device applications.
